(19) United States
(12) Patent Application Publication
(10) Pub. No.: US 2014/0192243 A1
(43) Pub. Date: Jul. 10, 2014

(54) IMAGE PICKUP DEVICE, METHOD OF MANUFACTURING SAME, AND ELECTRONIC APPARATUS

(71) Applicant: Sony Corporation, Tokyo (JP)

(72) Inventors: Tomohiro Iwahori, Kanagawa (JP); Yusuke Kikuchi, Kanagawa (JP); Koichi Tanigawa, Kumamoto (JP)

(73) Assignee: Sony Corporation, Tokyo (JP)

(21) Appl. No.: 14/146,386

(22) Filed: Jan. 2, 2014

(30) Foreign Application Priority Data
Jan. 9, 2013 (JP) 2013-001854

(51) Int. Cl. H04N 5/369; H01L 27/146

(52) U.S. Cl. CPC H04N 5/369; H01L 27/14623
USPC 348/302; 438/98

(57) ABSTRACT

An image pickup device with a plurality of pixels, each of the pixels includes: a photoelectric conversion section formed in a semiconductor substrate; and a metallic member formed between the semiconductor substrate and a wiring layer provided in a layer on the semiconductor substrate, a part of the metallic member being configured to serve as a light-shielding member that blocks a part of light to be incident on the photoelectric conversion section.

### CROSS REFERENCE TO RELATED APPLICATIONS

This application claims the benefit of Japanese Priority Patent Application JP2013-1854 filed Jan. 9, 2013, the entire contents of which are incorporated herein by reference.

### BACKGROUND

The present technology relates to an image pickup device, a method of manufacturing the same, and an electronic apparatus. In particular, the present technology relates to an image pickup device, a method of manufacturing the same, and an electronic apparatus that allow suppression of degradation in quality of an image, without increasing the number of manufacturing processes.

There has been an image pickup unit in which a phase difference detection pixel is mixed in multiple image pickup pixels of an image pickup device, to obtain image pickup signals from the image pickup pixels, and a phase difference detection signal from the phase difference detection pixel (for example, see Japanese Unexamined Patent Application Publication No. H01-216306 (JPH01-216306A)). In this image pickup unit, light to be incident on a photoelectric conversion section of the phase difference detection pixel is blocked by a first wiring layer provided above the photoelectric conversion section.

Meanwhile, there has been an image pickup unit in which light to be incident on a photoelectric conversion section of a phase difference detection pixel is blocked by forming a light-shielding mask at a position immediately above the photoelectric conversion section (for example, see Japanese Unexamined Patent Application Publication No. 2010-213253 (JP2010-213253A)).

### SUMMARY

In the image pickup unit of JP H01-216306A, it is necessary to focus on the first wiring layer to perform phase difference detection, in either of the phase difference detection pixel and the image pickup pixel. This may cause degradation in characteristics in the image pickup pixel, leading to degradation in quality of an image.

In the image pickup unit of JP 2010-213253A, a focal point may be set at a position lower than the position of the phase difference detection pixel in the image pickup unit of JP H01-216306A and therefore, degradation in characteristics in the image pickup pixel may be suppressed. However, it is necessary to provide a process of forming the light-shielding mask, in addition to a usual manufacturing process of the image pickup device.

It is desirable to suppress degradation in quality of an image, without increasing manufacturing processes.

According to an embodiment of the present technology, there is provided an image pickup device with a plurality of pixels, each of the pixels including: a photoelectric conversion section formed in a semiconductor substrate; and a metallic member formed between the semiconductor substrate and a wiring layer provided in a layer on the semiconductor substrate, a part of the metallic member being configured to serve as a light-shielding member that blocks a part of light to be incident on the photoelectric conversion section.

The pixels may be phase difference detection pixels each configured to generate a signal used to perform focusing determination based on phase difference detection.

The image pickup device may further include a plurality of image generation pixels each configured to generate a signal used to generate an image. The phase difference detection pixels may be dispersedly arranged among the plurality of image generation pixels that are arranged two-dimensionally in rows and columns.

Another part of the metallic member may serve as a contact that electrically connects the wiring layer to the semiconductor substrate.

The light-shielding member may be electrically connected to GND through the wiring layer.

The light-shielding member may be electrically connected to a power supply through the wiring layer.

The light-shielding member may be electrically floating.

Each of the pixels may be an image generation pixel that generates a signal used to generate an image.

According to an embodiment of the present technology, there is provided a method of manufacturing an image pickup device with a plurality of pixels, each of the pixels including a photoelectric conversion section formed in a semiconductor substrate, and a metallic member formed between the semiconductor substrate and a wiring layer provided in a layer on the semiconductor substrate. The method includes forming the metallic member to allow a part of the metallic member to serve as a light-shielding member that blocks a part of light to be incident on the photoelectric conversion section.

According to an embodiment of the present technology, there is provided an electronic apparatus with an image pickup device with a plurality of pixels, each of the pixels including: a photoelectric conversion section formed in a semiconductor substrate; and a metallic member formed between the semiconductor substrate and a wiring layer provided in a layer on the semiconductor substrate, a part of the metallic member being configured to serve as a light-shielding member that blocks a part of light to be incident on the photoelectric conversion section.

In the above-described embodiments of the present technology, each of the pixels includes the photoelectric conversion section and the metallic member. The photoelectric conversion section is formed in the semiconductor substrate. The metallic member is formed between the semiconductor substrate and the wiring layer provided in the layer on the semiconductor substrate. A part of the metallic member is configured to serve as the light-shielding member that blocks a part of light to be incident on the photoelectric conversion section.

According to the above-described embodiments of the present technology, degradation in quality of an image is allowed to be suppressed without increasing the number of manufacturing processes.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the present disclosure, and are incorporated in and constitute a part of this specification. The drawings illustrate embodiments and, together with the specification, serve to describe the principles of the technology.

FIG. 1 is a block diagram illustrating an example of an image pickup unit provided with an image sensor to which an embodiment of the present technology is applied.

FIG. 2 is a diagram used to describe a pixel arrangement of the image sensor.

FIG. 3 illustrates a cross-sectional diagram of each of an existing image generation pixel and an existing phase difference detection pixel.

FIG. 4 illustrates a cross-sectional diagram of each of an image generation pixel and a phase difference detection pixel according to an embodiment of the present technology.

FIG. 5 is a plan view of a phase difference detection pixel according to an embodiment of the present technology.

FIG. 6 is a plan view of a phase difference detection pixel according to an embodiment of the present technology.

FIG. 7 is a cross-sectional diagram of a phase difference detection pixel according to an embodiment of the present technology.

FIG. 8 is a cross-sectional diagram of a phase difference detection pixel according to an embodiment of the present technology.

FIG. 9 is a flowchart used to describe processing of forming a phase difference detection pixel.

FIG. 10 is a diagram used to describe processes of forming a phase difference detection pixel.

FIG. 11 is a block diagram illustrating another example of the image pickup unit provided with an image pickup device to which an embodiment of the present technology is applied.

FIG. 12 is a diagram used to describe a pixel arrangement of an AF sensor.

FIG. 13 is a diagram used to describe a pixel arrangement of an image sensor.

FIG. 14 is a cross-sectional diagram of an image generation pixel.

### DETAILED DESCRIPTION

Some embodiments of the present technology will be described below in detail with reference to the drawings.

### [Functional Configuration Example of Image Pickup Unit]

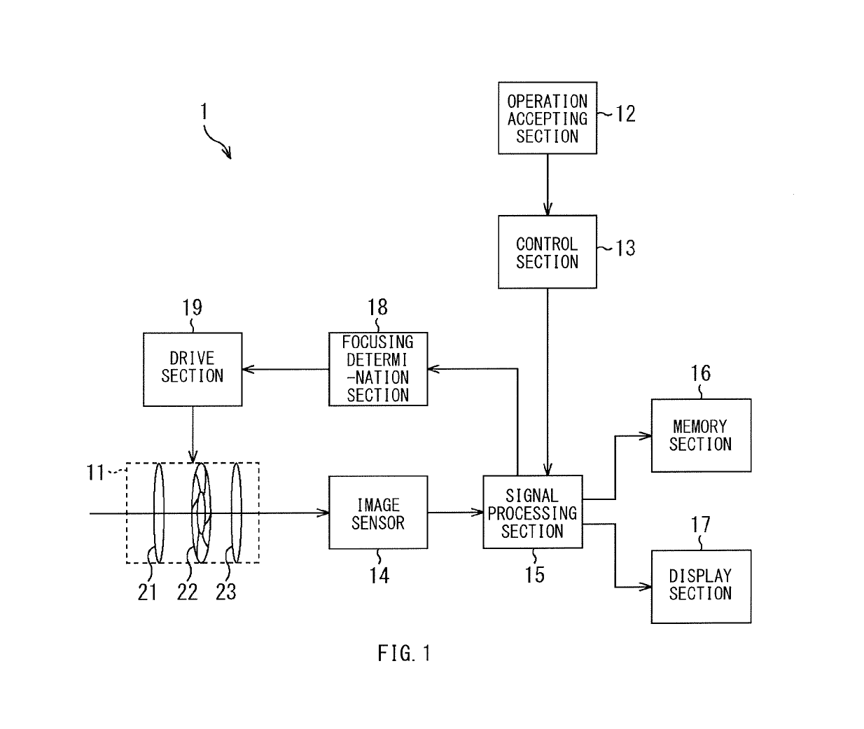

FIG. 1 is a block diagram illustrating an example of an image pickup unit provided with an image pickup device to which an embodiment of the present technology is applied.

An image pickup unit 1 of FIG. 1 picks up an image of a subject with the use of an AF (Auto Focus) function to generate a picked-up image, and records the picked-up image as a still image or a moving image. An example in which mainly a still image is recorded will be described below.

The image pickup unit 1 includes a lens section 11, an operation accepting section 12, a control section 13, an image sensor 14, a signal processing section 15, a memory section 16, a display section 17, a focusing determination section 18, and a drive section 19.

The lens section 11 condenses light (subject light) from a subject. The subject light condensed by the lens section 11 is incident on the image sensor 14.

The lens section 11 includes a zoom lens 21, a diaphragm 22, and a focus lens 23.

The zoom lens 21 is allowed to travel along an optical axis by being driven by the drive section 19 to vary a focal length, thereby adjusting the magnification of a subject to be included in a picked-up image. The diaphragm 22 changes the size of an aperture by being driven by the drive section 19, to adjust a light quantity of the subject light to be incident on the image sensor 14. The focus lens 23 is allowed to travel along the optical axis by being driven by the drive section 19, to adjust a focal point.

The operation accepting section 12 accepts operation from a user. For example, when a shutter button (not illustrated) is pressed, the operation accepting section 12 may supply the control section 13 with an operation signal indicating that the shutter button is pressed.

The control section 13 controls operation of each section of the image pickup unit 1.

For example, when accepting the operation signal indicating that the shutter button is pressed, the control section 13 may supply the signal processing section 15 with an instruction of recording a still image. Further, when causing the display section 17 to display a live-view image that is a real-time image of the subject, the control section 13 may supply the signal processing section 15 with an instruction of generating the live-view image.

Further, when performing focusing determination in a phase difference detection method, the control section 13 may supply the signal processing section 15 with an instruction of performing focusing determination operation (phase difference detection operation). The phase difference detection method is a focal-point detection method in which the degree of focusing is detected by forming a pair of images through pupil division of light which has passed through an image pickup lens, and then by measuring the distance between the formed images (an amount of displacement between the images) (i.e. by detecting a phase difference).

The image sensor 14 is an image pickup device that performs photoelectric conversion by which the received subject light is converted into an electric signal.

For example, the image sensor 14 may be configured of a CMOS (Complementary Metal Oxide Semiconductor) image sensor, a CCD (Charge Coupled Device) image sensor, or the like. A pixel (an image generation pixel) that generates a signal used to generate a picked-up image based on the received subject light, and a pixel (a phase difference detection pixel) that generates a signal used to perform phase difference detection are arranged in the image sensor 14. The image sensor 14 supplies the signal processing section 15 with the electric signal generated by the photoelectric conversion.

The signal processing section 15 applies various kinds of signal processing to the electric signal supplied from the image sensor 14.

For example, when an instruction of recording a still image is supplied from the control section 13, the signal processing section 15 may generate data of a still image (still-image data) and supply this data to the memory section 16. Further, when an instruction of generating a live-view image is supplied from the control section 13, the signal processing section 15 may generate data of a live-view image (live-view image data) based on an output signal from the image generation pixel in the image sensor 14, and supply this data to the display section 17.

Furthermore, when an instruction of performing phase difference detection operation is supplied from the control section 13, the signal processing section 15 may generate data (phase difference detection data) for detection of a phase difference, based on an output signal from the phase difference detection pixel in the image sensor 14, and supply the generated data to the focusing determination section 18.

The memory section 16 records the image data supplied from the signal processing section 15. For example, the memory section 16 may be configured as one or more removable recording media, examples of which may include a disk such as a DVD (Digital Versatile Disk) and a semiconductor memory such as a memory card. These recording media may be built in the image pickup unit 1, or may be removably mounted on the image pickup unit 1.

The display section 17 displays an image based on the image data supplied from the signal processing section 15. For example, the display section 17 may display a live-view image when the live-view image data is supplied from the signal processing section 15. The display section 17 may be configured of, for example, a color liquid crystal panel.

The focusing determination section 18 determines whether an object to be brought into focus (an object to be in focus) is in focus, based on the phase difference detection data supplied from the signal processing section 15. When an object in a focus area is in focus, the focusing determination section 18 supplies the drive section 19 with information indicating that the object is in focus as a focusing determination result. Further, when the object to be in focus is out of focus, the focusing determination section 18 calculates an amount of deviation in focusing (a defocus amount), and supplies the drive section 19 with information indicating the calculated defocus amount as a focusing determination result.

The drive section 19 drives the zoom lens 21, the diaphragm 22, and the focus lens 23. For example, the drive section 19 may calculate a drive quantity of the focus lens 23 based on the focusing determination result supplied from the focusing determination section 18, and allows the focus lens 23 to travel according to the calculated drive quantity.

Specifically, when the object to be in focus is in focus, the drive section 19 causes the focus lens 23 to remain at the current position. Further, when the object to be in focus is out of focus, the drive section 19 calculates a drive quantity (a travel distance) based on the focusing determination result indicating the defocus amount and the position of the focus lens 23, and allows the focus lens 23 to travel according to this drive quantity.

### [Pixel Arrangement of Image Sensor]

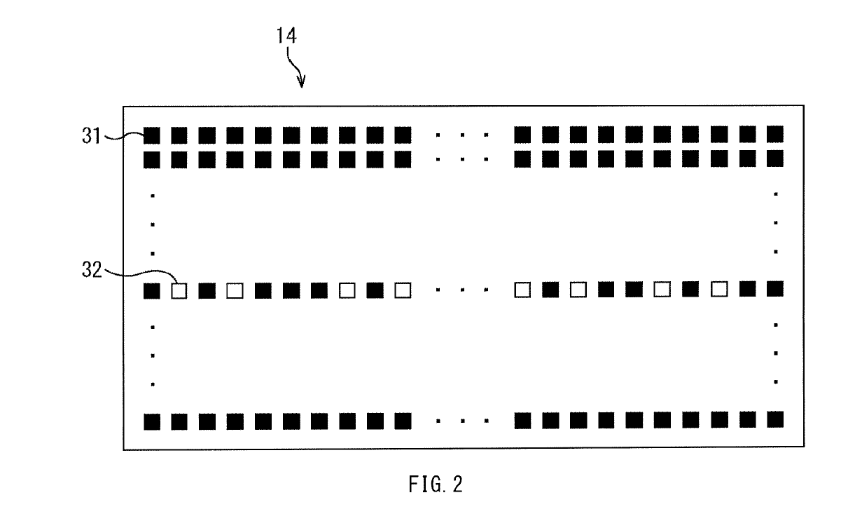

Next, a pixel arrangement of the image sensor 14 will be described with reference to FIG. 2.

In the image sensor 14, a plurality of image generation pixels 31 each indicated with a black square are two-dimensionally arranged in rows and columns, as illustrated in FIG. 2. The image generation pixels 31 are configured of R pixels, G pixels, and B pixels, and these pixels are arranged regularly in a Bayer array.

Further, in the image sensor 14, a plurality of phase difference detection pixels 32 each indicated with a white square are dispersedly arranged among the plurality of image generation pixels 31 that are arranged two-dimensionally in rows and columns. Specifically, the phase difference detection pixels 32 are regularly arranged in a specific pattern, by replacing part of the image generation pixels 31 in predetermined one of pixel rows in the image sensor 14.

Next, a detailed configuration of the phase difference detection pixel 32 in the image sensor 14 will be described. But first, a configuration of a phase difference detection pixel in an existing image sensor will be described.

### [Configuration of Pixel in Existing Image Sensor]

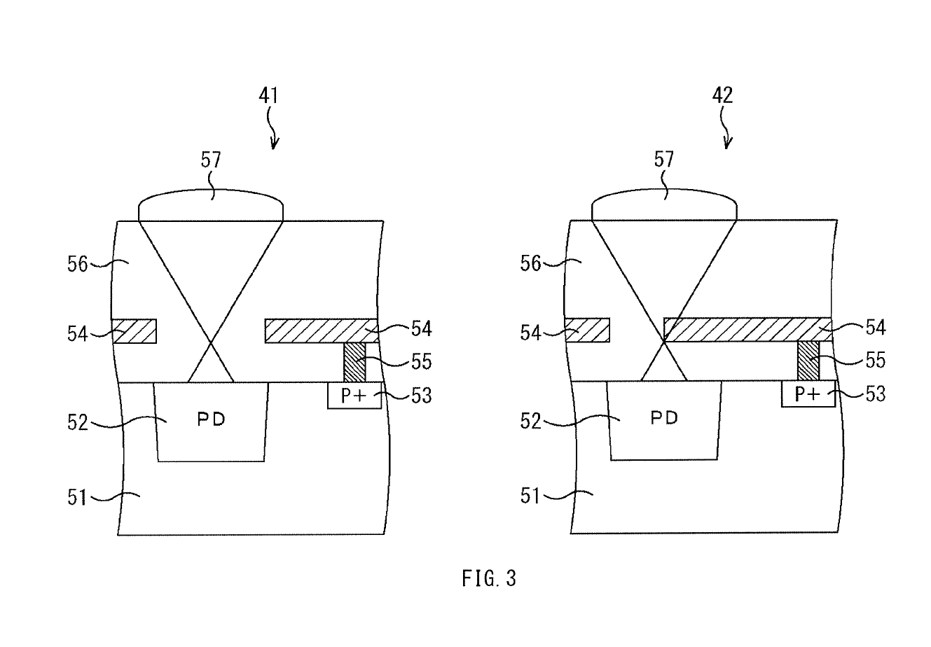

FIG. 3 illustrates a cross-sectional diagram of each of pixel configurations in an existing image sensor. In FIG. 3, a cross-sectional diagram of each of an image generation pixel 41 and a phase difference detection pixel 42 in the existing image sensor is illustrated.

In the image generation pixel 41, as illustrated in FIG. 3, a photoelectric conversion section 52 and a GND connection section 53 are formed in a semiconductor substrate 51. The GND connection section 53 is electrically connected to not-illustrated GND of the semiconductor substrate 51. In a layer on the semiconductor substrate 51, a wiring layer 54 made of Cu or Al is formed. Between the wiring layer 54 and the GND connection section 53, a contact 55 electrically connecting the wiring layer 54 and the GND connection section 53 is formed. The distance between a surface of the semiconductor substrate 51 and the wiring layer 54 may be about, for example, some hundreds of nanometers. On the wiring layer 54, an interlayer insulating film 56 is laminated, and a microlens 57 is formed on the interlayer insulating film 56. It is to be noted that a color filter having spectral characteristics corresponding to an R pixel, a G pixel, and a B pixel is formed between the interlayer insulating film 56 and the microlens 57, which is not illustrated.

In the image generation pixel 41, a light receiving region of the photoelectric conversion section 52 is defined by the wiring layer 54. However, since the wiring layer 54 is disposed without blocking subject light incident on the light receiving region of the photoelectric conversion section 52, the photoelectric conversion section 52 receives all the subject light passing through the microlens 57.

Meanwhile, in the phase difference detection pixel 42, the semiconductor substrate 51, the photoelectric conversion section 52, the GND connection section 53, the wiring layer 54, the contact 55, the interlayer insulating film 56, and the microlens 57 are also formed, as with the image generation pixel 41. It is to be noted that a neutral density filter, which is provided to reduce an incident light quantity equivalent to that of the color filter of the image generation pixel 41, is formed between the interlayer insulating film 56 and the microlens 57, which is not illustrated.

In the phase difference detection pixel 42, similarly, a light receiving region of the photoelectric conversion section 52 is defined by the wiring layer 54. However, the wiring layer 54 is disposed to block about a half of subject light to be incident on the light receiving region of the photoelectric conversion section 52. Therefore, in the phase difference detection pixel 42, the photoelectric conversion section 52 receives about a half of the subject light that has passed through the microlens 57.

In the image sensor provided with the image generation pixel 41 and the phase difference detection pixel 42 described above, it is necessary to focus on the wiring layer 54 for phase difference detection, in either of the image generation pixel 41 and the phase difference detection pixel 42. This may cause degradation in characteristics in an image pickup pixel, thereby leading to degradation in quality of an image.

### [Configuration of Pixel in Image Sensor of Embodiment of Present Technology]

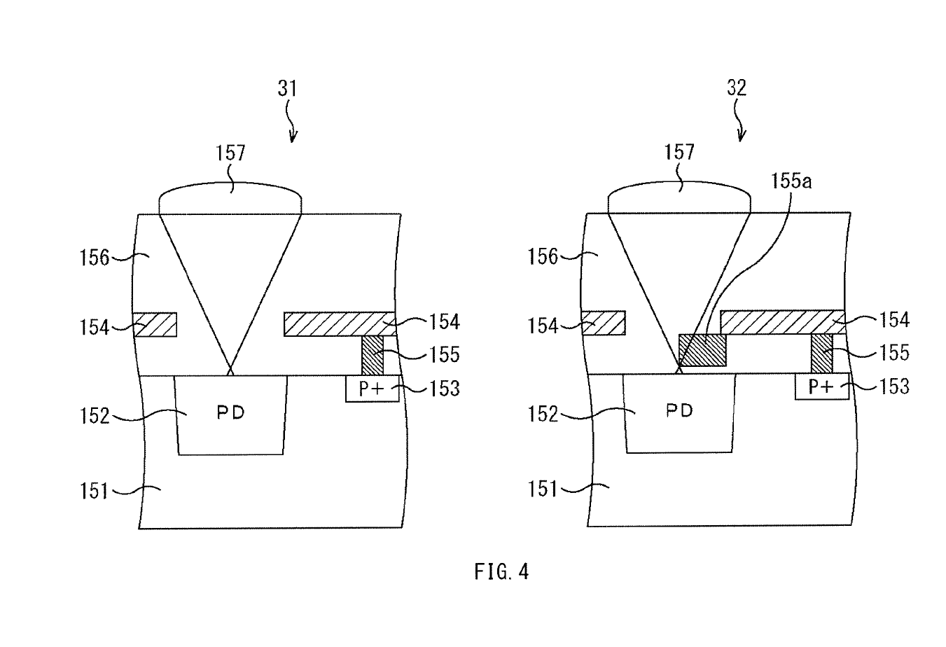

FIG. 4 illustrates a cross-sectional diagram of each of pixel configurations in the image sensor 14 to which the embodiment of the present technology is applied. In FIG. 4, a cross-sectional diagram of each of the image generation pixel 31 and the phase difference detection pixel 32 in the image sensor 14 is illustrated.

In the image generation pixel 31, a photoelectric conversion section 152 and a GND connection section 153 are formed in a semiconductor substrate 151, as illustrated in FIG. 4. The GND connection section 153 is electrically connected to not-illustrated GND of the semiconductor substrate 151. A wiring layer 154 made of Cu, Al, and/or the like is formed in a layer above the semiconductor substrate 151. Between the wiring layer 154 and the GND connection section 153, a contact 155 electrically connecting the wiring layer 154 and the GND connection section 153 is formed. The distance between a surface of the semiconductor substrate 151 and the wiring layer 154 may be, for example, about some hundreds of nanometers. On the wiring layer 154, an interlayer insulating film 156 is laminated, and a microlens 157 is formed on the interlayer insulating film 156. It is to be noted that a color filter having spectral characteristics corresponding to an R pixel, a G pixel, and a B pixel is formed between the interlayer insulating film 156 and the microlens 157, which is not illustrated.

In the image generation pixel 31, a light receiving region of the photoelectric conversion section 152 is defined by the wiring layer 154. However, since the wiring layer 154 is disposed without blocking subject light incident on the light receiving region of the photoelectric conversion section 152, the photoelectric conversion section 152 receives all the subject light that has passed through the microlens 157.

Meanwhile, in the phase difference detection pixel 32, the semiconductor substrate 151, the photoelectric conversion section 152, the GND connection section 153, the wiring layer 154, the contact 155, the interlayer insulating film 156, and the microlens 157 are also formed, as with the image generation pixel 31. It is to be noted that a neutral density filter, which is provided to reduce an incident light quantity equivalent to that of the color filter of the image generation pixel 31, is formed between the interlayer insulating film 156 and the microlens 157, which is not illustrated.

In the phase difference detection pixel 32, a light-shielding member 155a, which blocks about half of the subject light to be incident on the light receiving region of the photoelectric conversion section 152, is formed in the layer in which the contact 155 is formed. The contact 155 and the light-shielding member 155a are formed of the same metallic member such as tungsten (W). The distance between a surface of the semiconductor substrate 151 and the light-shielding member 155a may be, for example, about some hundreds of nanometers. Further, the light-shielding member 155a is formed so that a part thereof is connected to the wiring layer 154. The light-shielding member 155a is electrically connected to GND, through the wiring layer 154, the contact 155, and the GND connection section 153.

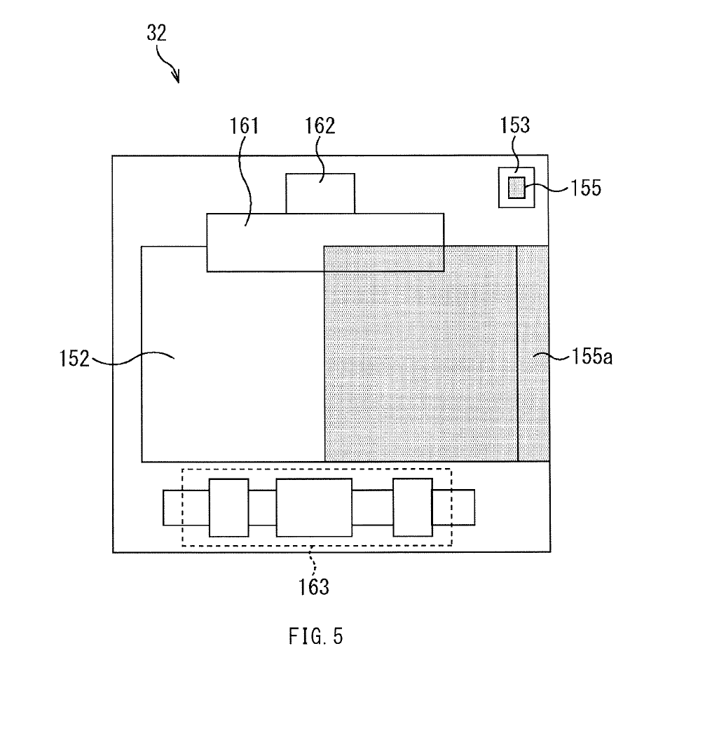

FIG. 5 is a plan view illustrating a configuration of the phase difference detection pixel 32. It is to be noted that the configuration excluding the layers on the contact 155 and the light-shielding member 155a is illustrated in FIG. 5.

In the phase difference detection pixel 32 of FIG. 5, a transfer gate 161, a floating diffusion (FD) 162, and a pixel transistor 163 are illustrated, in addition to the photoelectric conversion section 152, the GND connection section 153, the contact 155, and the light-shielding member 155a.

The transfer gate 161 transfers an electric charge, which is generated in the photoelectric conversion section 152 and corresponds to an incident light quantity, to the FD 162. The pixel transistor 163 includes a reset transistor, an amplifying transistor, and a select transistor.

In the phase difference detection pixel 32 of FIG. 5, the light-shielding member 155a is formed to shield the right half of the light receiving region of the photoelectric conversion section 152, in FIG. 5.

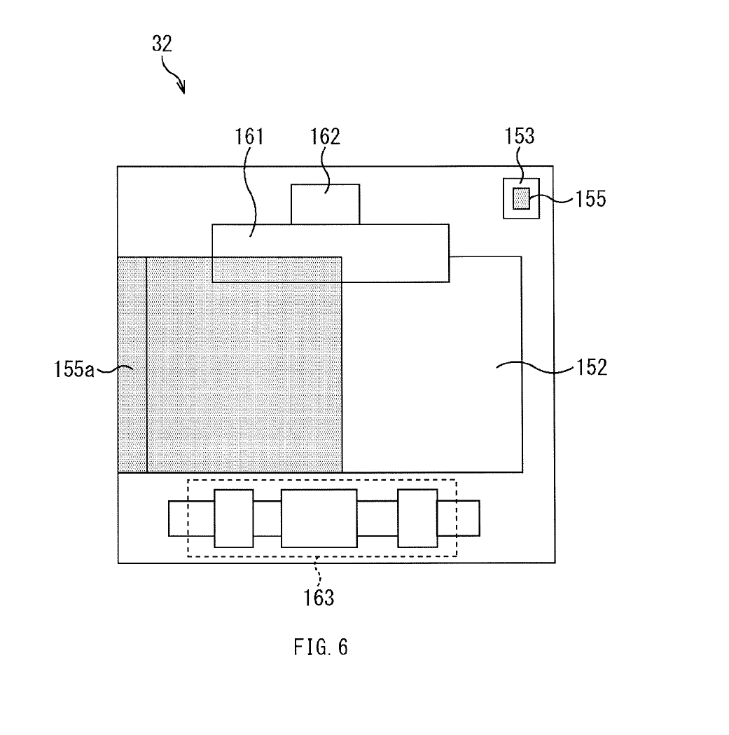

FIG. 6 is a plan view illustrating a configuration of the phase difference detection pixel 32 that is paired with the phase difference detection pixel 32 illustrated in FIG. 5, in the phase difference detection. In the phase difference detection pixel 32 of FIG. 6, the light-shielding member 155a shields the left half of the light receiving region of the photoelectric conversion section 152, in FIG. 6.

In the phase difference detection pixel 32 configured as described above, the photoelectric conversion section 152 receives about a half of the subject light passing through the microlens 57.

In the image sensor 14 provided with the image generation pixel 31 and the phase difference detection pixel 32 as described above, it is necessary to focus on the light-shielding member 155a for the phase difference detection, in either of the image generation pixel 31 and the phase difference detection pixel 32. The light-shielding member 155a is formed in the layer in which the contact 155 is formed, namely, the layer that is closer to the semiconductor substrate 151 (the photoelectric conversion section 152) than the wiring layer 154. Therefore, the focal point may be set at a position lower than the position of the phase difference detection pixel 42 of FIG. 3. Thus, in the image generation pixel 31, it is possible to reduce degradation in characteristics, and thereby to allow degradation in quality of an image to be reduced.

Further, the light-shielding member 155a is electrically connected to the GND through the wiring layer 154, the contact 155, and the GND connection section 153. Therefore, adverse effects such as fluctuation of a signal that may be caused by parasitic capacitance between the light-shielding member 155a and other wiring are eliminated, which makes it possible to stabilize electrical characteristics of the pixel.

In the above description, the light-shielding member 155a is electrically connected to the GND, but may be electrically connected to a power supply.

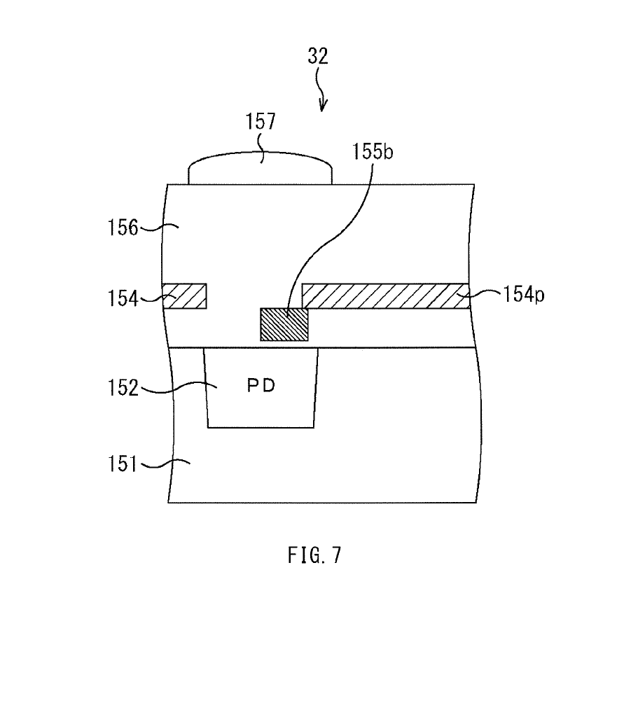

Specifically, as illustrated in FIG. 7, a light-shielding member 155b may be electrically connected to a not-illustrated power supply through a wiring layer 154p, by being formed so that a part of the light-shielding member 155b is connected to the wiring layer 154p that is connected to the power supply.

Further, the light-shielding member may be electrically floating.

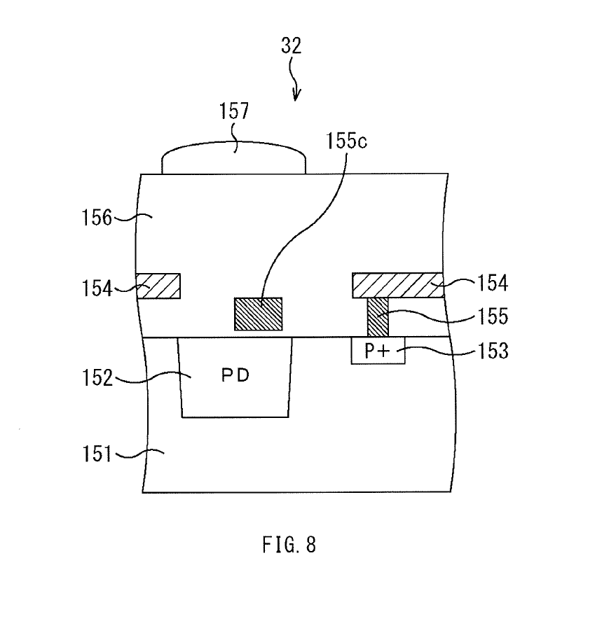

Specifically, as illustrated in FIG. 8, a light-shielding member 155c may be electrically floating, by being formed not to be connected to the wiring layer 154.

Furthermore, the light-shielding member may be electrically connected to the FD 162 through a wiring layer, which is not illustrated.

### [Processing of Forming Phase Difference Detection Pixel]

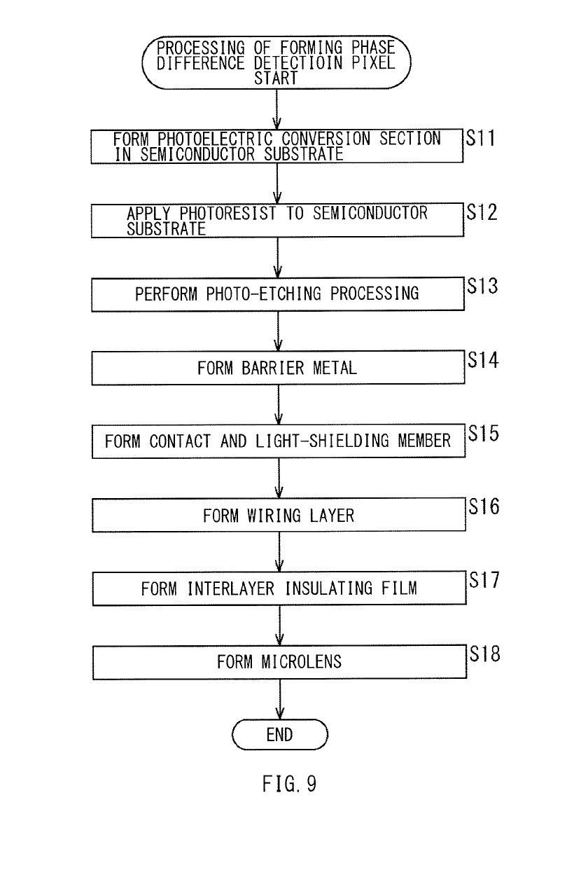

Next, processing of forming the above-described phase difference detection pixel 32 will be described with reference to a flowchart of FIG. 9.

In step S11, the photoelectric conversion section 152 is formed in the semiconductor substrate 151. The photoelectric conversion section 152 is formed by performing ion implantation into the semiconductor substrate 151. Subsequently, the GND connection section 153 is similarly formed by performing ion implantation into the semiconductor substrate 151.

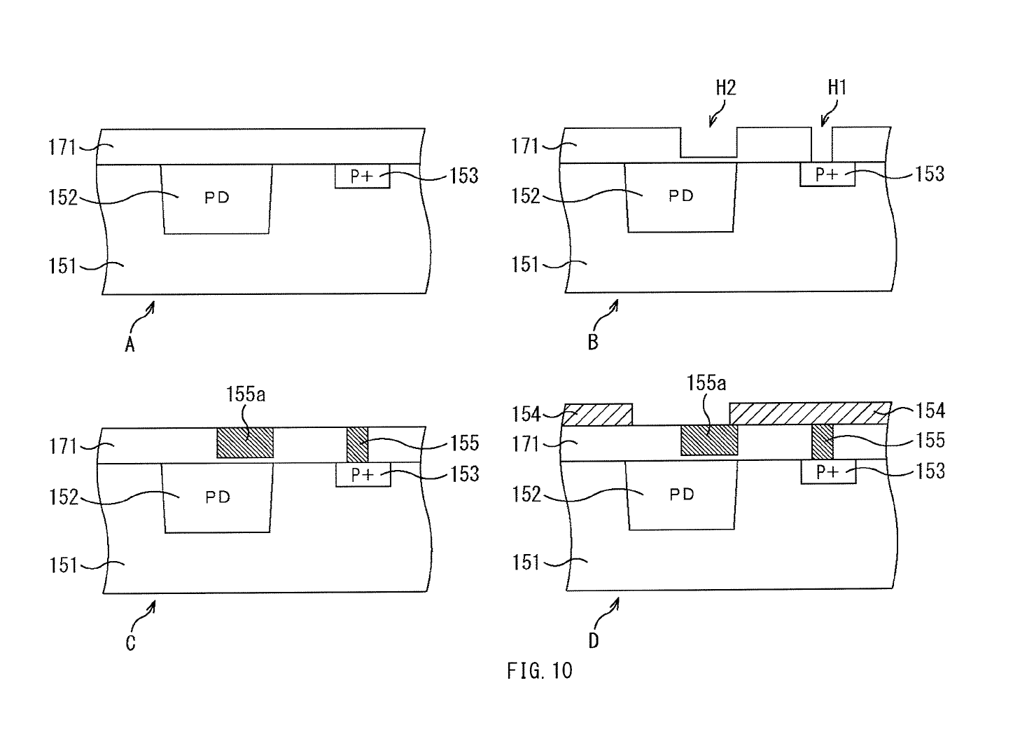

In step S12, as illustrated in a state A of FIG. 10, a photoresist 171 is applied to the semiconductor substrate 151 in which the photoelectric conversion section 152 and the GND connection section 153 are formed. In this example, the applied photoresist 171 may have a film thickness of, for example, about some hundreds of nanometers.

In step S13, photo-etching processing is performed. As a result, a hole H1 is formed on the GND connection section 153, and a hole H2 is formed above the photoelectric conversion section 152, as illustrated in a state B of FIG. 10. It is to be noted that the hole H1 is formed to reach the surface of the semiconductor substrate 151, and the hole H2 is formed not to reach the surface of the semiconductor substrate 151. A part of the photoresist 171 remaining in the bottom of the hole H2 may have a film thickness of, for example, about 100 nm. It is to be noted that the contact 155 is to be formed in the hole H1, and the light-shielding member 155a is to be formed in the hole H2, as will be described later.

In step S14, a barrier metal is formed in the hole H1. Examples of the barrier metal may include TiN and Ti. It is to be noted that the light-shielding member 155a and a surface of the photoelectric conversion section 152 will not be electrically connected and therefore, a barrier metal is not formed in the hole H2.

In step S15, the contact 155 and the light-shielding member 155a are formed by depositing tungsten in the holes H1 and H2, as illustrated in a state C of FIG. 10.

In step S16, the wiring layer 154 is formed by depositing Cu or Al through sputtering, as illustrated in a state D of FIG. 10. The wiring layer 154 is processed by performing lithography. It is to be noted that the wiring layer is not limited to a single layer, and may be in a multilayer structure including two or more layers.

In step S17, the interlayer insulating film 156 is formed on the wiring layer 154. On the interlayer insulating film 156, a neutral density filter may be formed.

In step S18, the microlens 157 is formed on the interlayer insulating film 156. Thus, the phase difference detection pixel 32 is formed.

In the above processing, the light-shielding member 155a is formed in the layer in which the contact 155 is formed, namely, in the layer closer to the semiconductor substrate 151 (the photoelectric conversion section 152) than the wiring layer 154. Therefore, a focal point may be set at a position lower than that in the phase difference detection pixel 42 of FIG. 3. In addition, the light-shielding member 155a is formed in the process in which the contact 155 is formed. Therefore, it is not necessary to increase the number of processes by adding a process of forming a light-shielding mask to an existing manufacturing process of an image pickup device. Thus, in the image generation pixel 31, it is possible to reduce degradation in characteristics and therefore, degradation in quality of an image is allowed to be reduced without increasing the number of manufacturing processes.

### Another Embodiment

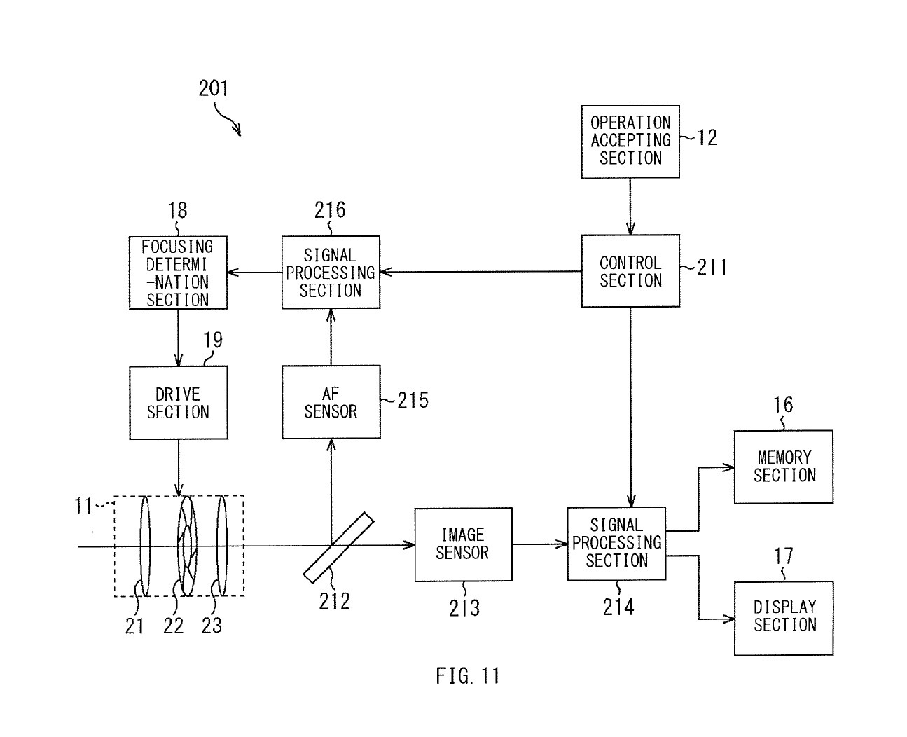

FIG. 11 is a block diagram illustrating another example of an image pickup unit provided with an image pickup device to which an embodiment of the present technology is applied.

An image pickup unit 201 of FIG. 11 includes a lens section 11, an operation accepting section 12, a memory section 16, a display section 17, a focusing determination section 18, a drive section 19, a control section 211, a pellicle mirror 212, an image sensor 213, a signal processing section 214, an AF sensor 215, and a signal processing section 216.

It is to be noted that, in the image pickup unit 201 of FIG. 11, configurations having functions similar to those provided in the image pickup unit 1 of FIG. 1 are provided with the same names and the same reference numerals as those of the image pickup unit 1, and the description thereof will be omitted as appropriate.

The control section 211 controls operation of each section of the image pickup unit 201.

For example, when accepting an operation signal indicating that a shutter button is pressed, the control section 211 may supply the signal processing section 214 with an instruction of recording a still image. Further, when causing the display section 17 to display a live-view image, the control section 211 may supply the signal processing section 214 with an instruction of generating the live-view image.

Furthermore, when causing focusing determination in a phase difference detection method to be performed, the control section 211 may supply the signal processing section 216 with an instruction of performing phase difference detection operation.

The pellicle mirror 212 divides subject light condensed through the lens section 11 into two. The pellicle mirror 212 may be, for example, a semitransparent-type mirror. The pellicle mirror 212 divides the subject light into two beams by reflecting about 30% of the subject light, and supplies one of the two beams of the divided subject light to the image sensor 213, and the other to the AF sensor 215.

The image sensor 213 is an image pickup device that receives the one of the two beams of the subject light divided by the pellicle mirror 212, and performs photoelectric conversion by which the received subject light is converted into an electric signal.

For example, the image sensor 213 may be configured of, for example, a CMOS image sensor, a CCD image sensor, or the like. In the image sensor 213, image generation pixels, each generating a signal used to generate a picked-up image based on the received subject light, are arranged in a Bayer array. The image sensor 213 supplies the electric signal generated by the photoelectric conversion, to the signal processing section 214.

The signal processing section 214 applies various kinds of signal processing to the electric signal supplied from the image sensor 213.

When an instruction of recording a still image is supplied from the control section 211, the signal processing section 214 generates data (still-image data) of a still image, and supplies the generated data to the memory section 16. Further, when an instruction of generating a live-view image is supplied from the control section 211, the signal processing section 214 generates data (live-view image data) of a live-view image based on an output signal from the image generation pixel in the image sensor 213, and supplies the generated data to the display section 17.

The AF sensor 215 is an image pickup device that receives the other of the two beams of the subject light divided by the pellicle mirror 212, and performs photoelectric conversion by which the received subject light is converted into an electric signal.

For example, the AF sensor 215 may be configured of, for example, a CMOS image sensor, a CCD image sensor, or the like. A phase difference detection pixel that generates a signal used to perform phase difference detection may be disposed in the AF sensor 215. The AF sensor 215 supplies the electric signal generated by the photoelectric conversion, to the signal processing section 216.

The signal processing section 216 applies various kinds of signal processing to the electric signal supplied from the AF sensor 215.

For example, when an instruction of performing the phase difference detection operation is supplied from the control section 211, the signal processing section 216 may generate data (phase difference detection data) for detection of a phase difference, based on an output signal from the phase difference detection pixel in the AF sensor 215, and supply the generated data to the focusing determination section 18.

### [Pixel Arrangement of AF Sensor]

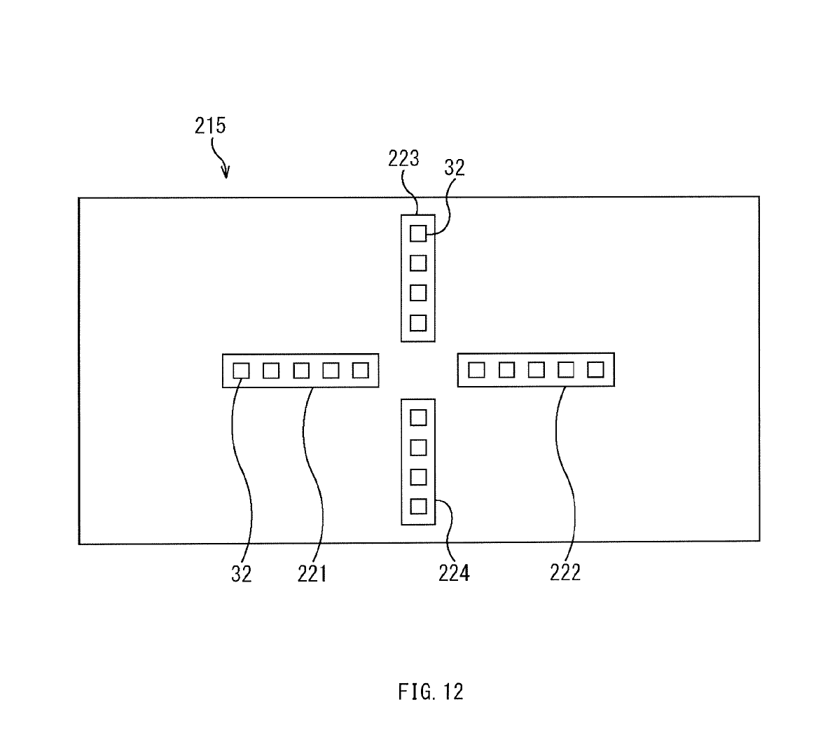

Next, a pixel arrangement of the AF sensor 215 will be described with reference to FIG. 12.

As illustrated in FIG. 12, the AF sensor 215 includes line sensors 221 and 222 disposed in series in a lateral direction with respect to each other, and line sensors 223 and 224 disposed in series in a vertical direction with respect to each other. In each of the line sensors 221 to 224, the above-described phase difference detection pixels 32 are disposed in series.

In this way, the image pickup device according to the above-described embodiment of the present technology may be applied to an AF sensor such as the AF sensor illustrated in FIG. 12.

It is to be noted that the arrangement of the line sensors in the AF sensor 215 is not limited to that illustrated in FIG. 12, and may be other type of arrangement.

Further, the examples in which the embodiments of the present technology are applied to the image pickup device provided in the image pickup unit that focuses by performing the phase difference detection have been described above. However, the embodiments of the present technology may be applied to an image pickup device provided in an image pickup unit that focuses in other AF method.

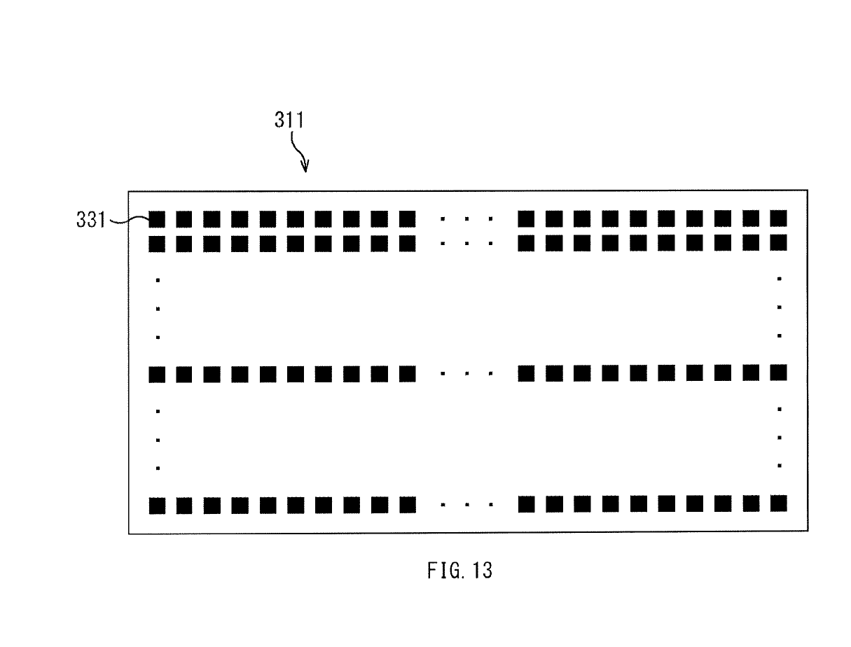

FIG. 13 is a diagram used to describe a pixel arrangement of an image sensor that may be provided in, for example, an image pickup unit that focuses in a contrast AF method.

As illustrated in FIG. 13, a plurality of image generation pixels 331 each indicated by a black square are arranged two-dimensionally in rows and columns, in an image sensor 311. The image generation pixels 331 are formed of R pixels, G pixels, and B pixels, and these pixels are arranged regularly in a Bayer array.

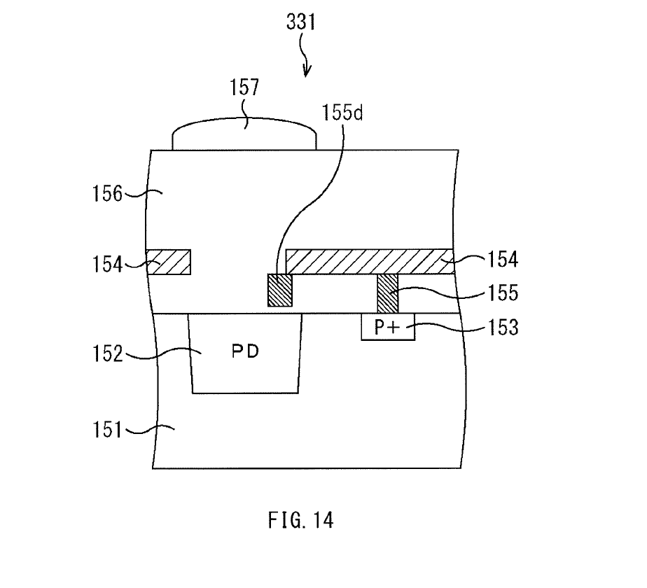

FIG. 14 is a cross-sectional diagram illustrating a configuration of the image generation pixel 331.

It is to be noted that, in the image generation pixel 331 of FIG. 14, configurations having functions similar to those provided in the phase difference detection pixel 32 of FIG. 4 are provided with the same names and the same reference numerals as those of the phase difference detection pixel 32, and the description thereof will be omitted as appropriate.

In other words, in the image generation pixel 331, a light-shielding member 155d, which shields part of subject light to be incident on a light receiving region of the photoelectric conversion section 152, is formed in the layer in which the contact 155 is formed.

In this way, the image pickup device according to the above-described embodiment of the present technology may be applied to an image sensor made of only image generation pixels and performing so-called ordinary photography, like the image sensor illustrated in FIG. 13.

It is to be noted that, the image pickup device according to the above-described embodiment of the present technology may be provided in other type of electronic apparatus having an image pickup function, without being limited to the above-described image pickup units.

Further, an embodiment of the present technology is not limited to those described above, and may be variously modified within a scope not departing from the gist of the present technology.

It is possible to achieve at least the following configurations from the above-described example embodiments and the modifications of the disclosure.

(1) An image pickup device with a plurality of pixels, each of the pixels including:

a photoelectric conversion section formed in a semiconductor substrate; and

a metallic member formed between the semiconductor substrate and a wiring layer provided in a layer on the semiconductor substrate, a part of the metallic member being configured to serve as a light-shielding member that blocks a part of light to be incident on the photoelectric conversion section.

(2) The image pickup device according to (1), wherein the pixels are phase difference detection pixels each configured to generate a signal used to perform focusing determination based on phase difference detection.
(3) The image pickup device according to (2), further including

a plurality of image generation pixels each configured to generate a signal used to generate an image, wherein

the phase difference detection pixels are dispersedly arranged among the plurality of image generation pixels that are arranged two-dimensionally in rows and columns.

(4) The image pickup device according to any one of (1) to (3), wherein another part of the metallic member serves as a contact that electrically connects the wiring layer to the semiconductor substrate.
(5) The image pickup device according to any one of (1) to (3), wherein the light-shielding member is electrically connected to GND through the wiring layer.
(6) The image pickup device according to any one of (1) to (3), wherein the light-shielding member is electrically connected to a power supply through the wiring layer.
(7) The image pickup device according to any one of (1) to (3), wherein the light-shielding member is electrically floating.
(8) The image pickup device according to (1), wherein each of the pixels is an image generation pixel that generates a signal used to generate an image.
(9) A method of manufacturing an image pickup device with a plurality of pixels, each of the pixels including

a photoelectric conversion section formed in a semiconductor substrate, and

a metallic member formed between the semiconductor substrate and a wiring layer provided in a layer on the semiconductor substrate,

the method including:

forming the metallic member to allow a part of the metallic member to serve as a light-shielding member that blocks a part of light to be incident on the photoelectric conversion section.

(10) An electronic apparatus with an image pickup device with a plurality of pixels, each of the pixels including:

a photoelectric conversion section formed in a semiconductor substrate; and

a metallic member formed between the semiconductor substrate and a wiring layer provided in a layer on the semiconductor substrate, a part of the metallic member being configured to serve as a light-shielding member that blocks a part of light to be incident on the photoelectric conversion section.

It should be understood by those skilled in the art that various modifications, combinations, sub-combinations, and alterations may occur depending on design requirements and other factors insofar as they are within the scope of the appended claims or the equivalents thereof.

What is claimed is:

1. An image pickup device with a plurality of pixels, each of the pixels comprising:
a photoelectric conversion section formed in a semiconductor substrate; and
a metallic member formed between the semiconductor substrate and a wiring layer provided in a layer on the semiconductor substrate, a part of the metallic member being configured to serve as a light-shielding member that blocks a part of light to be incident on the photoelectric conversion section.

2. The image pickup device according to claim 1, wherein the pixels are phase difference detection pixels each configured to generate a signal used to perform focusing determination based on phase difference detection.

3. The image pickup device according to claim 2, further comprising
a plurality of image generation pixels each configured to generate a signal used to generate an image, wherein
the phase difference detection pixels are dispersedly arranged among the plurality of image generation pixels that are arranged two-dimensionally in rows and columns.

4. The image pickup device according to claim 2, wherein another part of the metallic member serves as a contact that electrically connects the wiring layer to the semiconductor substrate.

5. The image pickup device according to claim 2, wherein the light-shielding member is electrically connected to GND through the wiring layer.

6. The image pickup device according to claim 2, wherein the light-shielding member is electrically connected to a power supply through the wiring layer.

7. The image pickup device according to claim 2, wherein the light-shielding member is electrically floating.

8. The image pickup device according to claim 1, wherein each of the pixels is an image generation pixel that generates a signal used to generate an image.

9. A method of manufacturing an image pickup device with a plurality of pixels, each of the pixels including
a photoelectric conversion section formed in a semiconductor substrate, and
a metallic member formed between the semiconductor substrate and a wiring layer provided in a layer on the semiconductor substrate,
the method comprising:
forming the metallic member to allow a part of the metallic member to serve as a light-shielding member that blocks a part of light to be incident on the photoelectric conversion section.

10. An electronic apparatus with an image pickup device with a plurality of pixels, each of the pixels comprising:
a photoelectric conversion section formed in a semiconductor substrate; and
a metallic member formed between the semiconductor substrate and a wiring layer provided in a layer on the semiconductor substrate, a part of the metallic member being configured to serve as a light-shielding member that blocks a part of light to be incident on the photoelectric conversion section.
